(19) United States
(12) Patent Application Publication
(10) Pub. No.: US 2002/0168869 A1
(43) Pub. Date: Nov. 14, 2002

(54) Method for fabricating an ONO layer

(76) Inventors: Kent Kuohua Chang, Taipei City (TW); Hsiang-Lan Lung, Hsin-Chu City (TW); Fuh-Cheng Jong, Tai-Nan City (TW)

Correspondence Address: NAIPO (NORTH AMERICA INTERNATIONAL PATENT OFFICE), P.O. BOX 506, MERRIFIELD, VA, 22116, US

(21) Appl. No.: 09/851,573

(22) Filed: May 10, 2001

(51) Int. Cl. H01L 21/31

(52) U.S. Cl. 438/769; 438/770; 438/779

(57) ABSTRACT

A substrate is first provided, and a first oxide layer is formed on the surface of the substrate. A rapid thermal nitrifying (RTN) process anneals the first oxide layer and simultaneously nitrifies the surface of the first oxide layer. Then, a low-pressure chemical vapor deposition (LPCVD) process forms a nitride layer on the surface of the first oxide layer. Finally, a second oxide layer is formed on the surface of the nitride layer. The second oxide layer, the nitride layer and the first oxide layer together construct the ONO layer.

### BACKGROUND OF THE INVENTION

1. Field of the Invention

The present invention relates to a method of fabricating an ONO layer of a nitride read only memory (NROM) cell.

2. Description of the Prior Art

A read only memory (ROM) device, comprising a plurality of memory cells, is a type of semiconductor wafer device that functions as a data storage device. The ROM device is widely applied in computer data storage and memory, and depending on the method of storing data, the ROM can be divided into several types such as a mask ROM, programmable ROM (PROM), erasable programmable ROM (EPROM), and an electrically erasable programmable ROM (EEPROM).

Differing from other types of ROMs that use a polysilicon or metal floating gate, a nitride read only memory (NROM) uses an insulating dielectric layer as a charge-trapping medium. Due to the highly compacted nature of the silicon nitride layer, hot electrons tunneling from the MOS transistor into the silicon nitride layer are trapped within to form an unequal concentration distribution to increase data reading speed and avoid current leakage.

Please refer to FIG. 1 of a schematic diagram of a standard structure of an NROM according to the prior art. A semiconductor wafer 10 comprises a P-type silicon substrate 12, two N-type doped areas 14, 16 positioned on the surface of the silicon substrate 12, an ONO dielectric structure 24, and a gate conductor layer 26 positioned on the ONO dielectric structure 24. The ONO dielectric structure 24 is composed of a bottom oxide layer 18, a silicon nitride layer 20 and a top oxide layer 22.

Please refer to FIG. 2 and FIG. 3. FIG. 2 and FIG. 3 are schematic diagrams of a method for fabricating an NROM using the standard structure shown in FIG. 1. As shown in FIG. 2, according to the prior art for fabricating a gate of the NROM, a semiconductor wafer 30 comprising a P-type silicon 32 is first provided. A high temperature oxidation process is performed to form an oxide layer with a thickness of 50-150 angstroms as a bottom oxide layer 34 on the surface of the silicon substrate 32. Then, a low-pressure chemical vapor deposition (LPCVD) is used to deposit a silicon nitride layer 36 with a thickness of 50-150 angstroms on the bottom oxide layer 34. An annealing process is then used under a high temperature of 950° C. for a duration of 30 minutes to repair the structure of the silicon nitride layer 36. Also, water steam is injected to perform a wet oxidation process to form a silicon oxy-nitride layer with a thickness of 50-150 angstroms as a top oxide layer 38. The bottom oxide layer 34, the silicon nitride layer 36 and the top oxide layer 38 comprises the ONO dielectric structure 40 on the surface of the silicon substrate 32.

As shown in FIG. 3, a photolithographic and etching process is performed to form a gate pattern in the top oxide layer 38 and silicon nitride layer 36. An ion implantation process is then performed to form a plurality of doped areas 42 as a source and drain in the MOS transistor. Thereafter, a thermal oxidation process is used to form a field oxide (FOX) 44 on the surface of the source/drain to isolate each silicon nitride layer 36. Finally, a doped polysilicon layer 46 is deposited as a gate conductor layer.

According to the prior art for forming a top oxide layer, the process requires a higher temperature and thermal budget to form an oxide layer on the surface of the nitride compound. Thus, the higher temperature may lead to the degradation of the gate oxide layer and affect the reliability of the NROM. Furthermore, because of the discontinuity of the interface between silicon substrate and bottom oxide layer and the unsaturated bondings of the interface, some trapped charges exist within the bottom oxide layer and thus vary the threshold voltage within the layer.

### SUMMARY OF THE INVENTION

It is therefore a primary objective of the present invention to provide a method of fabricating an ONO layer for improving the electrical property of the bottom oxide layer, so as to improve the programming and erasing efficiency, and reliability of the NROM.

In accordance with the claimed invention, the method first forms a first oxide layer on the surface of the silicon substrate of a semiconductor wafer. A rapid thermal nitridation (RTN) process is then performed for annealing the first oxide layer and simultaneously nitrifying the surface of the first oxide layer. Next, a low-pressure chemical vapor deposition (LPCVD) process is performed to form a nitride layer on the surface of the first oxide layer. Finally, a second oxide layer is formed on the surface of the nitride layer. The second oxide layer, the nitride layer and the first oxide layer together construct the ONO layer.

The present invention uses a RTN process for annealing the bottom oxide layer and simultaneously nitrifying the surface of the bottom oxide layer. Therefore, the nitrogen atoms accumulated in the interface between the silicon substrate and bottom oxide layer release the mechanical stress and saturate the dangling bonds that exist between the bottom oxide layer and the silicon substrate so as to improve the dielectric properties of the bottom oxide layer.

### BRIEF DESCRIPTION OF THE DRAWINGS

FIG. 1 is a schematic diagram of a standard structure of an NROM according to the prior art.

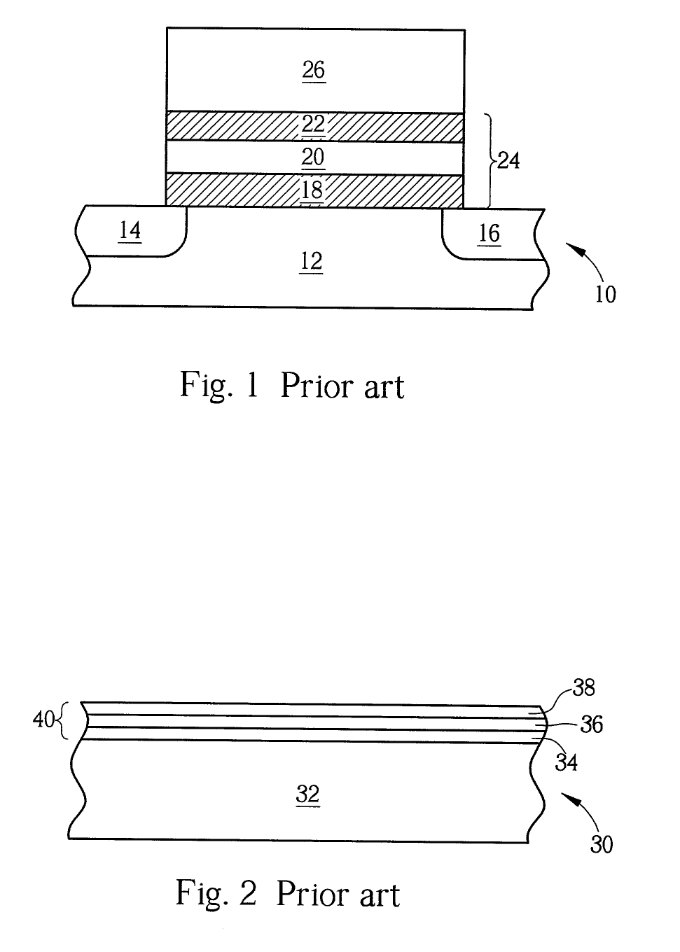

FIG. 2 and FIG. 3 are schematic diagrams of a method for fabricating an NROM using the standard structure shown in FIG. 1.

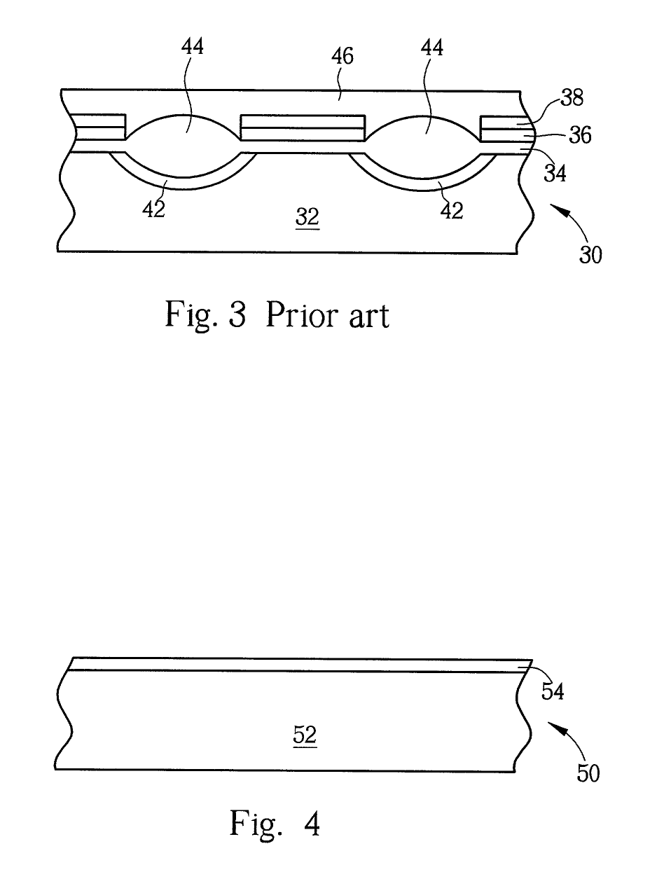

FIG. 4 to FIG. 6 are schematic diagrams of a method for fabricating the ONO layer of an NROM according to the prior invention.

### DESCRIPTION OF THE PREFERRED EMBODIMENT

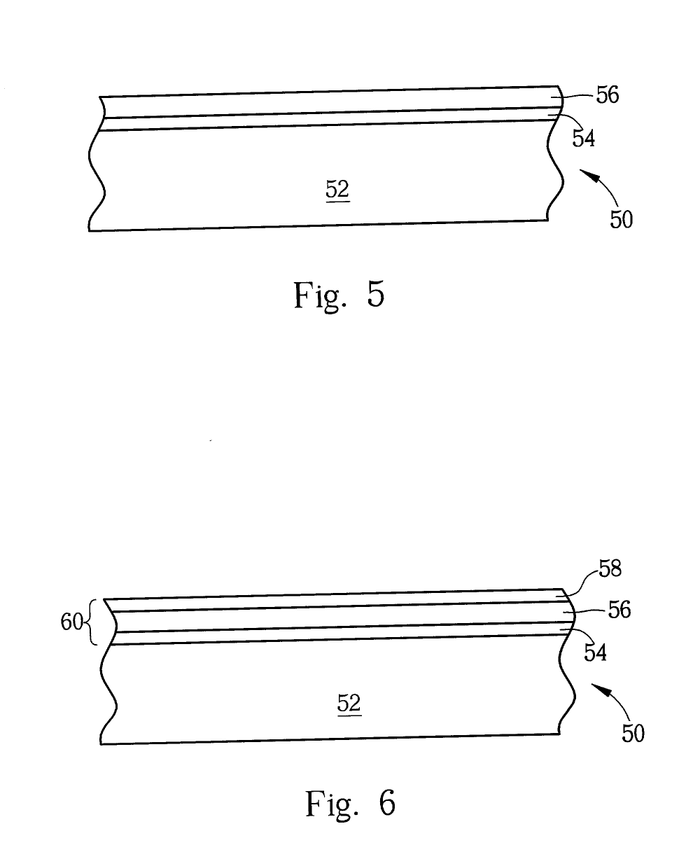

Please refer to FIG. 4 to FIG. 6. FIG. 4 to FIG. 6 are schematic diagrams of a method for fabricating the ONO layer of an NROM according to the present invention. As shown in FIG. 4, the ONO layer according to the present invention is fabricated on the surface of the silicon substrate 52 or the silicon-on-insulator (SOI) substrate (not shown) of a semiconductor wafer 50. A high temperature oxidation process is performed to oxidize the silicon surface of the substrate 52 so as to form a bottom oxide layer 54 with a thickness of 40-100 angstroms as a tunneling oxide layer of an nitride read only memory (NROM) . The thermal oxidation process using oxygen (O₂) and T-LC (Cl₂) as precursors is performed at a temperature of 800° C. and in a nitrogen-and-oxygen-containing (N₂/O₂) environment.

Following, a rapid thermal nitrifying (RTN) process is performed on the bottom oxide layer 54. The process uses nitrous oxide (N₂O) or nitric oxide (NO) as a reacting gas at a temperature of 800-1050° C. for annealing the bottom oxide layer 52 and simultaneously nitrifying the surface of the bottom oxide layer 54 with a duration of 60 seconds. For example, nitrous oxide (N₂O) or nitric oxide (NO) used as a reacting gas is aerated at a temperature of 900° C., or nitrous oxide (N₂O) or nitric oxide (NO) used as a reacting gas is aerated at a temperature of 950° C., with a duration of 60 seconds. The method of nitrifying the surface of the bottom oxide layer 54 also comprises a nitrogen plasma process, a nitrogen ion implantation process or a nitrogen-containing solution soaking process.

Then as shown in FIG. 5, a low-pressure chemical vapor deposition (LPCVD) is performed to form a nitride layer 56 on the surface of the oxide layer 54. The temperature and pressure of the LPCVD process are 700° C. and 0.6 Torr respectively, and the LPCVD process uses dichlorosilane (SiCl₂H₂, DCS), ammonia (NH₃) and nitrogen (N₂) as reacting gases so as to form a nitride layer 56 with a thickness of 110-150 angstroms on the surface of the bottom oxide layer 54.

Finally as shown in FIG. 6, another thermal oxidation process is performed at a temperature of 1000° C. and in a steam-containing environment for oxidizing the surface of the nitride layer 56 so as to form a top oxide layer 58 with a thickness approximately 90 angstroms (Å). The top oxide layer 58, the nitride layer 56 and the bottom oxide layer 54 together construct the ONO layer 60 of an NROM.

The present invention uses a RTN process for annealing the bottom oxide layer and simultaneously nitrifying the surface of the bottom oxide layer. Therefore, the properties of the oxide layer are improved to reduce the charge trapping effect of the bottom oxide layer and narrow the distribution of the threshold voltage.

In contrast to the prior art method for fabricating the ONO layer of an NROM, the present invention uses a RTN process to improve the properties of the bottom oxide layer so as to reduce the flat band voltage shift and the variation of Fowler-Nordheim voltage. Therefore, the programming and erasing efficiency, and reliability of the NROM is increased. Furthermore, the present invention method may also be applied in the manufacturing process of the ONO layer in ordinary devices such as capacitors.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for fabricating an oxide-nitride-oxide (ONO) layer, the method comprising:
providing a substrate;
forming a first oxide layer on the surface of the substrate;
performing a rapid thermal nitridation (RTN) process for annealing the first oxide layer and simultaneously nitrifying the surface of the first oxide layer;
forming a nitride layer on the surface of the first oxide layer; and
forming a second oxide layer on the surface of the nitride layer, the second oxide layer, the nitride layer and the first oxide layer together construct the ONO layer.

2. The method of claim 1 wherein the substrate is a silicon substrate or a silicon-on-insulator (SOI) substrate.

3. The method of claim 2 wherein the first oxide layer is formed by performing a first thermal oxidation process to oxidize the silicon surface of the substrate, with the thickness of the first oxide layer between 40 and 100 angstroms (Å).

4. The method of claim 3 wherein the first thermal oxidation process is performed at a temperature of 800° C. and in a nitrogen-and-oxygen-containing (N₂/O₂) environment.

5. The method of claim 4 wherein the precursors of the first thermal oxidation process are oxygen (O₂) and T-LC (Cl₂).

6. The method of claim 1 wherein the duration of the RTN process is 60 seconds, the temperature of the process is between 800 to 1050° C., and the reacting gas of the RTN process is nitrous oxide (N₂O) or nitric oxide (NO).

7. The method of claim 1 wherein the thickness of the nitride layer is between 110 to 150 angstroms (Å).

8. The method of claim 1 wherein the nitride layer is formed by performing a low-pressure chemical vapor deposition (LPCVD) process.

9. The method of claim 8 wherein the temperature and pressure of the LPCVD process are 700° C. and 0.6 Torr respectively, and the reacting gases of the LPCVD process comprise dichlorosilane (SiCl₂H₂, DCS), ammonia (NH₃) and nitrogen (N₂).

10.The method of claim 1 wherein the second oxide layer is formed by performing a second thermal oxidation process to oxidize the surface of the nitride layer, with the thickness of the second oxide layer approximately 90 angstroms (Å).

11. The method of claim 10 wherein the second thermal oxidation process is performed at a temperature of 1000° C. and in a steam-containing environment.

12. The method of claim 1 wherein the first oxide layer serves as a tunneling oxide layer of a nitride read only memory (NROM).

13. A method for fabricating an oxide-nitride-oxide (ONO) layer, the method comprising:
providing a substrate;
forming a first oxide layer on the surface of the substrate;
performing a surface treatment to the first oxide layer;
forming a nitride layer on the surface of the first oxide layer; and
forming a second oxide layer on the surface of the nitride layer, the second oxide layer, the nitride layer and the first oxide layer together construct the ONO layer.

14. The method of claim 13 wherein the substrate is a silicon substrate or a silicon-on-insulator (SOI) substrate.

15. The method of claim 14 wherein the first oxide layer is formed by performing a thermal oxidation process to oxidize the silicon surface of the substrate, which serves as a tunneling oxide layer of a nitride read only memory (NROM), with the thickness of the first oxide layer between 40 and 100 angstroms (Å).

16. The method of claim 15 wherein the thermal oxidation process is performed at a temperature of 800° C. and in a nitrogen-and-oxygen-containing (N₂/O₂) environment, the precursors of the thermal oxidation process are oxygen (O₂) and T-LC(Cl₂).

17. The method of claim 13 wherein the surface treatment comprises an annealing process, a nitrogen plasma process, a nitrogen ion implantation process or a nitrogen-containing solution soaking process.

18. The method of claim 17 wherein the annealing process is a rapid thermal nitridation (RTN) process using nitrous oxide (N₂O) or nitric oxide (NO) as reacting gases at a temperature between 800 to 1050° C. for a duration of 60 seconds.

19. The method of claim 13 wherein the nitride layer is formed by performing a low-pressure chemical vapor deposition (LPCVD) process, with the thickness of the nitride layer between 110 and 150 angstroms (Å).

20. The method of claim 19 wherein the temperature and pressure of the LPCVD process is respectively 700° C. and 600 mTorr, and the reacting gases of the LPCVD process comprise dichlorosilane (SiCl₂H₂, DCS), ammonia (NH₃) and nitrogen (N₂).

21. The method of claim 13 wherein the thickness of the second oxide layer is approximately 90 angstroms (Å), which is formed by oxidizing the surface of the nitride layer at a temperature of 1000° C. and in a steam-containing environment.
